(19) United States
(12) Patent Application Publication
(10) Pub. No.: US 2014/0104502 A1
(43) Pub. Date: Apr. 17, 2014

(54) TELEVISION RECEIVER AND ELECTRONIC DEVICE

(71) Applicant: Kabushiki Kaisha Toshiba, Tokyo (JP)

(72) Inventor: Mitsuyoshi Takao, Hidaka-shi (JP)

(21) Appl. No.: 13/907,422

(22) Filed: May 31, 2013

(30) Foreign Application Priority Data
Oct. 12, 2012 (JP) 2012-227486

(51) Int. Cl. H05K 7/00; H04N 5/64

(52) U.S. Cl. CPC H05K 7/00; H04N 5/64
USPC 348/836; 361/679.01

(57) ABSTRACT

According to one embodiment, a television receiver includes a housing, a support, a first member, and a second member. The housing includes a display device. The support is configured to rotatably support the housing. The first member is configured to be supported by the support and includes a planar first surface. The second member is configured to be supported by the housing and includes a planar second surface configured to be rotated while being rubbed against the first surface as the housing rotates. The support includes: a first opening in which a first protrusion provided to the first member is inserted; and a second opening in which a second protrusion provided to the second member is inserted. The second opening communicates with the first opening. The second protrusion is configured to be rotated between a first position and a second position as the housing rotates.

### CROSS-REFERENCE TO RELATED APPLICATIONS

This application is based upon and claims the benefit of priority from Japanese Patent Application No. 2012-227486, filed Oct. 12, 2012, the entire contents of which are incorporated herein by reference.

### FIELD

Embodiments described herein relate generally to a television receiver and an electronic device.

### BACKGROUND

Conventionally, there is known a television receiver or an electronic device in which an angle of a display screen of a display device can be set variably.

Such television receiver or electronic device is preferred to comprise a movable support mechanism with less inconveniences, e.g., a mechanism that can prevent increase in size.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of one example of a television receiver as viewed from a front side thereof according to an embodiment;

FIG. 2 is an exemplary perspective view of one example of the television receiver as viewed from a rear side thereof, in the embodiment;

FIG. 3 is an exemplary side view of a portion including a support of one example of the television receiver in the embodiment;

FIG. 4 is an exemplary perspective view of a portion including the support of one example of the television receiver in the embodiment;

FIG. 5 is an exemplary cross-sectional view of the portion illustrated in FIG. 3 of one example of the television receiver in the embodiment;

FIG. 6 is an exemplary exploded perspective view of a portion including the support of one example of the television receiver, in the embodiment;

FIG. 7 is an exemplary exploded perspective view of a portion including the support of one example of the television receiver as viewed from a different angle from that in FIG. 6, in the embodiment;

FIG. 8 is an exemplary exploded perspective view of a portion of the support of one example of the television receiver in the embodiment; and

FIG. 9 is an exemplary plan view of a member comprised in the support of one example of the television receiver in the embodiment.

### DETAILED DESCRIPTION

In general, according to one embodiment, a television receiver comprises a housing, a support, a first member, and a second member. The housing comprises a display device. The support is configured to rotatably support the housing. The first member is configured to be supported by the support and comprises a planar first surface. The second member is configured to be supported by the housing and comprises a planar second surface configured to be rotated while being rubbed against the first surface as the housing rotates. The support comprises: a first opening in which a first protrusion provided to the first member is inserted; and a second opening in which a second protrusion provided to the second member is inserted, the second opening communicating with the first opening, the second protrusion being configured to be rotated between a first position and a second position as the housing rotates.

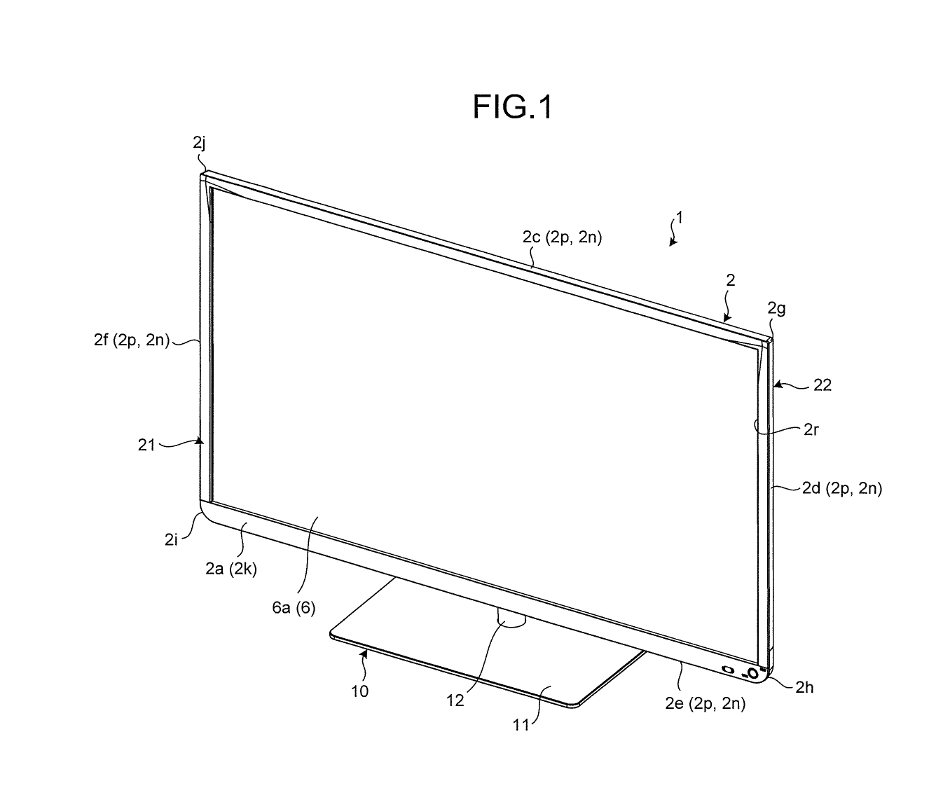

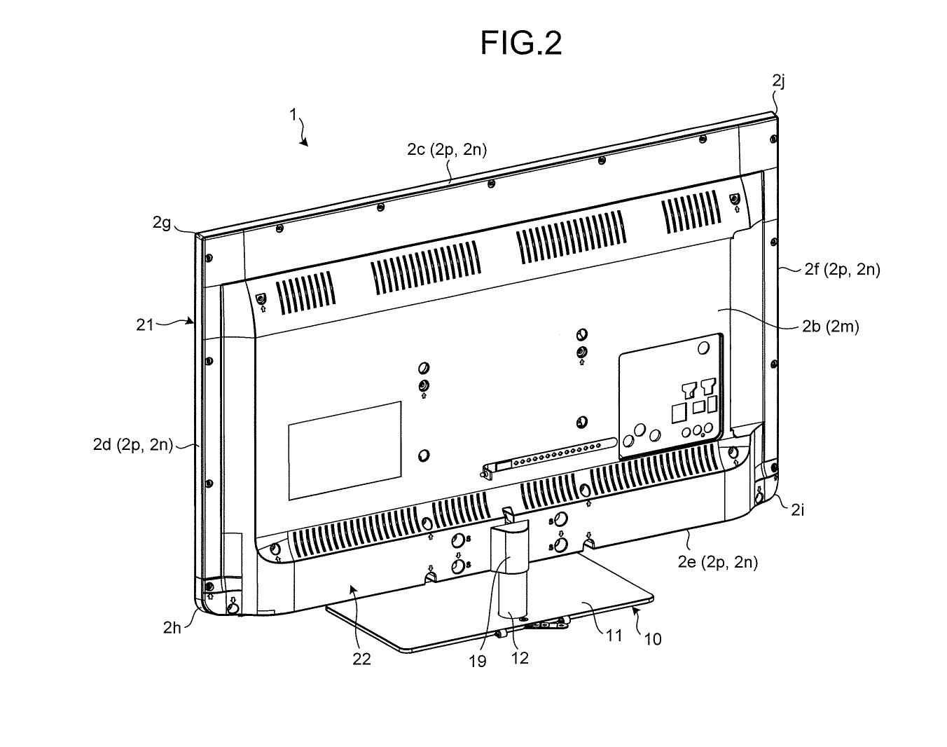

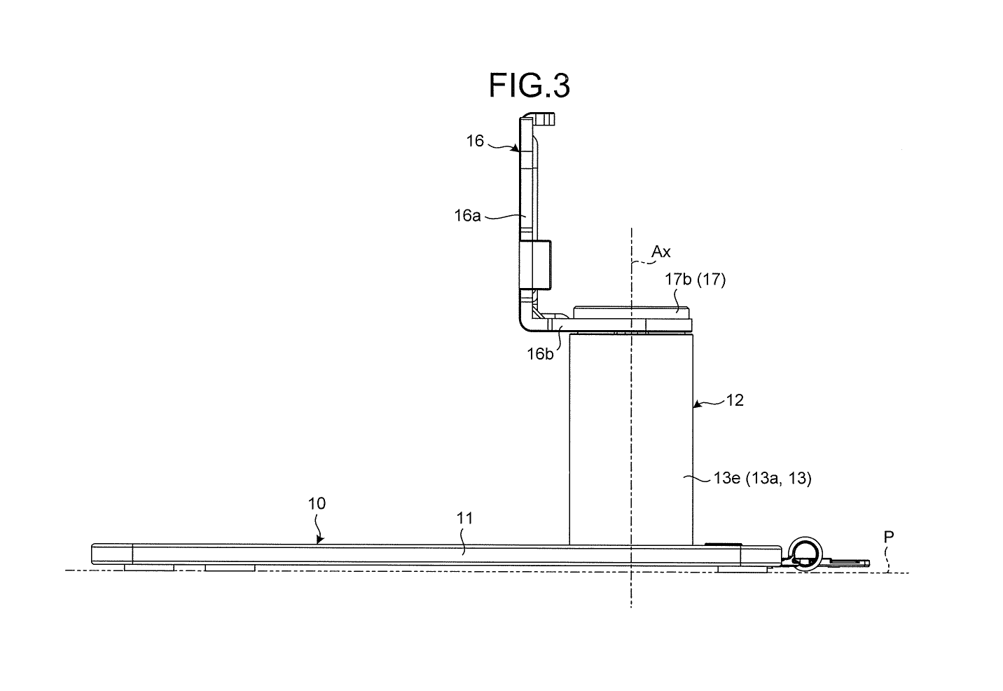

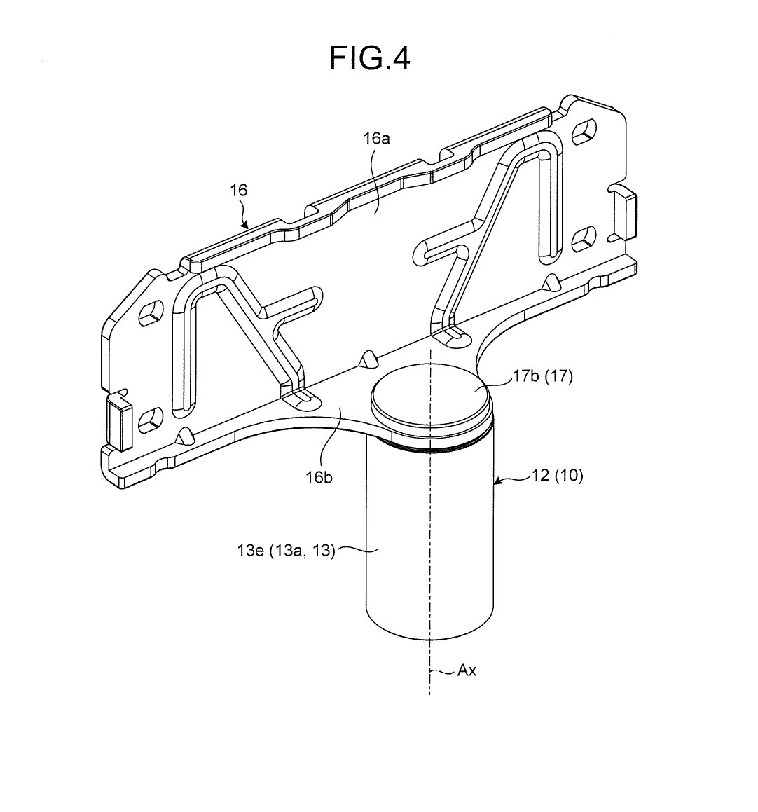

A television receiver 1 that is an example of an electronic device according to the embodiment comprises a support 10 (a supporting portion, a station, a stand) and a housing 2, as illustrated in FIGS. 1 and 2. The support 10 is placed on a setting area such as a stand, a desk, and a shelf (a setting surface P; see FIG. 3), and supports the housing 2. The support 10 supports the housing 2 in a rotatable (movable, displaceable, slidable) manner. In the embodiment, as an example, the support 10 supports the housing 2 at least in a horizontally rotatable manner about a rotation axis Ax extending in the vertical direction (see FIGS. 3 and 4). In other words, in the embodiment, as an example, the television receiver 1 enables a display device 6 to be at least swiveled (to be rotated about the rotation axis Ax).

In this embodiment, as an example, as illustrated in FIGS. 1 and 2, the housing 2 has a rectangular shape (in this embodiment, an oblong shape, as an example) in the front view (and the rear view). The housing 2 also has a cuboid shape that is thin and flat in the front-back direction. The housing 2 comprises a surface 2a (a facing surface, a frontal side of the front surface) and a surface 2b (a back surface, a rear surface, a behind surface) opposite the surface 2a. The surface 2a and the surface 2b are approximately in parallel with respect to each other. The housing 2 also comprises four ends 2c to 2f (side portions, edge portions) and four corners 2g to 2j (pointed portions, curved portions, ends) in the front view (and the rear view). The ends 2c and 2e are examples of a long side. The ends 2d and 2f are examples of a short side.

As an example, the housing 2 comprises a wall 2k (a front wall, a frontal wall) and a wall 2m (a rear wall, a back wall). The wall 2k comprises the surface 2a. The wall 2m comprises the surface 2b. The wall 2k has a rectangular, frame-like, and plate-like shape (in this embodiment, as an example, an oblong frame-like and plate-like shape). The wall 2m has a rectangular plate-like shape (in this embodiment, an oblong plate-like shape, as an example). The housing 2 also comprises, as an example, four walls 2n (side walls, end walls, standing walls, stretching portions). Each of the walls 2n comprises a side surface 2p (a side surface, a circumferential surface) extended between the wall 2k and the wall 2m. The wall 2k has a rectangular opening 2r, as an example. The housing 2 may be made of a material such as a synthetic resin or a metal.

The housing 2 may also comprise a combination of a plurality of components (members, divided bodies). In this embodiment, as an example, the housing 2 comprises a member 21 (a front side member, a frame, a bezel, a cover) and a second member 22 (a rear side member, a base, a bottom, a case). The member 21 at least comprises the wall 2k. The member 22 at least comprises the wall 2m. The walls 2n may be comprised in at least one of the first member 21 and the second member 22 (in this embodiment, as an example, in the second member 22).

At least a portion of the display device 6 (a display module, a display, a panel) is housed in the housing 2. In this embodiment, as an example, a surface 6a (a display screen) of the display device 6 on the side of the surface 2a is exposed to the front side (outside) of the housing 2 through the opening 2r, and a user can see the surface 6a through the opening 2r from the front side. Images (videos) are displayed on the surface 6a. In this embodiment, as an example, the display device 6 has a rectangular shape (in this embodiment, an oblong shape, as an example) in the front view. The display device 6 also has a cuboid shape that is thin and flat in the front-back direction. The display device 6 is a liquid crystal display (LCD) or an organic electro-luminescent display (OELD), as an example. A thin, transparent, and plate-like or sheet-like touch panel (an input panel, an input sheet, an input device; not illustrated) or a cover covering the surface 6a may be provided to the front surface of the display device 6.

In this embodiment, as an example, aboard (a control board, a main board, a circuit board; not illustrated) is housed in the housing 2 on the rear side (back side, behind side, the side nearer to the wall 2m, a side opposite the surface 6a) of the display device 6. The board is laid in parallel with the surface of the display device 6 (back surface, not illustrated) at the side opposite the surface 6a of the display device 6. The board is positioned in a manner interspaced with the walls 2k, 2m, 2n, and the like. In other words, the board is positioned in a manner so that a space is ensured between the board and the walls 2k, 2m, 2n, and the like. The board is fixed to the display device 6 or the housing 2 with couplers (not illustrated) such as screws.

A plurality of components (electric components, electronic components, elements; not illustrated), such as a central processing unit (CPU), and connectors are mounted on the board. The components may include a heating element. A cooling mechanism (e.g., a heat receiving element, a heat conducting element, a heat radiator, or a fan not illustrated) may be provided correspondingly to a component generating a large amount of heat (a heating element). The board and the components make up at least a portion of a controlling circuit (not illustrated). The controlling circuit may comprise a video signal processing circuit, a tuner, a high-definition multimedia interface (HDMI) signal processor, an audio video (AV) input terminal, a remote controller signal receiver, a controller, a selector, an on-screen display, a storage (e.g., a read-only memory (ROM), a random access memory (RAM), a hard disk drive (HDD)), and an audio signal processing circuit, for example. The controlling circuit controls video outputs (e.g., moving images or still images) from the surface 6a of the display device 6, audio outputs from a speaker (not illustrated), and light emissions from a light emitting diode (LED) (not illustrated). The display device 6, the speaker, the LED, and the like are examples of an output module.

The support 10 is placed on the setting surface P (see FIG. 3) such as a stand or a desk, and rotatably (movably, displaceably) supports the housing 2. As illustrated in FIGS. 1 to 4, in the embodiment, as an example, the support 10 comprises a base 11 and a post 12. Specifically, the base 11 has an appearance of a rectangle (oblong) when viewed from the top (in the direction perpendicular to the setting surface P, up-and-down direction), and of a plate that is thin in the up-and-down direction and flat across directions along the setting surface P (in other words, has an appearance of a rectangular plate). The post 12 protrudes upward from the base 11 (a direction away from the setting surface P, a direction intersecting with (perpendicular to) the setting surface P) in a shape of a cylinder.

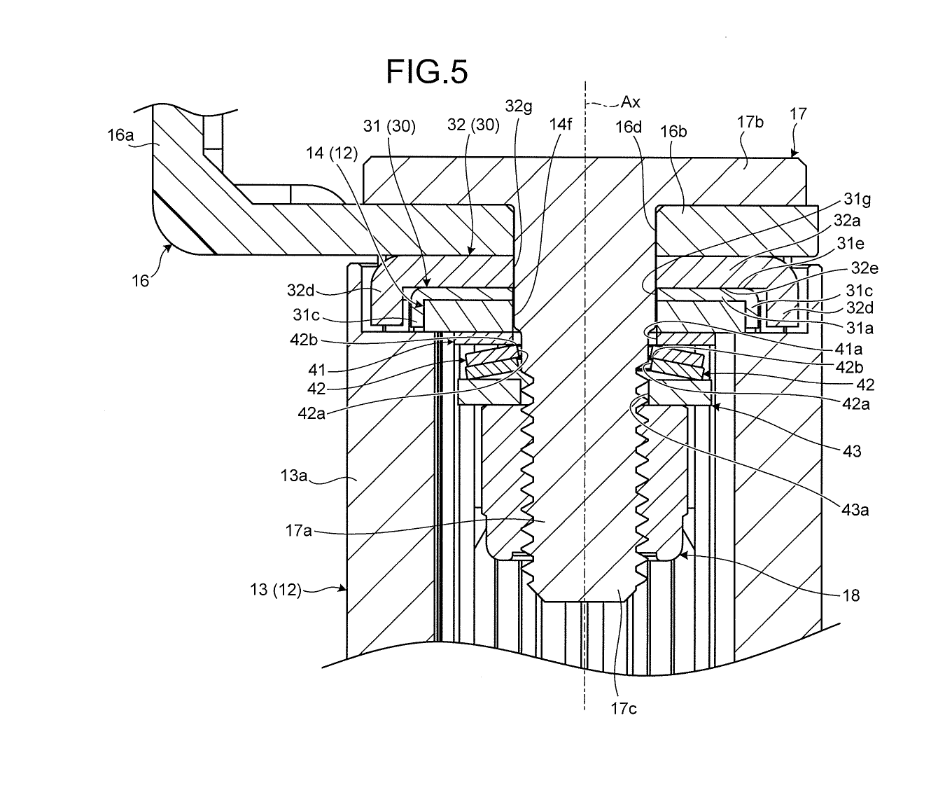

In the embodiment, as an example, as illustrated in FIGS. 5 to 7, the post 12 comprises a member 13 and a member 14. The member 13 has a tubular shape (in the embodiment, as an example, a cylindrical shape). The member 13 comprises a wall 13a (side wall) and ribs 13b (protrusions). The wall 13a has a tubular shape, and extends along the rotation axis Ax. A plurality of the ribs 13b protrude from the wall 13a toward an internal space 13c in the tube (toward the inner side in the radial direction), and extends in the axial direction (up-and-down direction). The ribs 13b can improve the stiffness of the member 13, and of the post 12 itself in turn. The member 13 is an example of a fifth member. The member 14 (wall) has a circular, plate-like shape (disk-like shape). The member 14 extends along a direction intersecting with (direction perpendicular to) the rotation axis Ax. The member 14 covers one end of the internal space 13c of the member 13. The member 14 is an example of a fourth member and a support member. The member 13 and the member 14 are coupled (connected, fixed, integrated) using couplers 15 (in the embodiment, as an example, screws). Specifically, coupled portions 13d (in the embodiment, as an example, female screws) are formed on the ribs 13b of the member 13, and the member 14 is provided with openings 14a (in the embodiment, as an example, through-holes) through which the couplers 15 pass. The member 13 and the member 14 are coupled (integrated) by fixing the couplers 15 penetrating through the respective openings 14a to the coupled portions 13d, respectively. The members 13, 14 may be made of a metallic material. The member 13 may be manufactured by extrusion molding. Because such manufacturing process can achieve a smooth surface on a surface 13e (external surface) of the member 13, additional processes such as polishing and painting applied to the surface 13e can be reduced or omitted. The member 13 may be made of an aluminum alloy, as an example. The member 14 may be made of a ferrous material (e.g., stainless steel), as an example. In the embodiment, as an example, these two members 13, 14 realize a tubular post 12 with a base (an upper base, a top wall, a base wall). By configuring the post 12 from a plurality of members, the stiffness or the strength can be increased locally, and labors or costs required in manufacturing the post 12 can be reduced.

In the embodiment, as an example, a member 16 is fixed to the housing 2. The member 16 is interposed between the support 10 and the housing 2. The member 16 is an example of a connector (a bracket, a connecting member, a fixing member) connecting the support 10 and the housing 2 with each other. The member 16 has a wall 16a (a part) and a wall 16b (a part). The wall 16a and the wall 16b are configured in an L-shape, as illustrated in FIGS. 3, 6, and 7. The wall 16a is placed in an overlapping manner with the rear side of the wall 2m of the housing 2, and is coupled to (connected to, fixed to, integrated with) the wall 2m with couplers (as an example, screws not illustrated). In the configuration in which the member 16 is mounted on the housing 2, the wall 16b protrudes from the wall 16a (the wall 2m) toward the rear side of the housing 2, in the direction approximately in parallel with the setting surface P. The wall 16b extend across directions intersecting with (direction perpendicular to) the rotation axis Ax. The wall 16b is provided in parallel with the member 14 of the post 12. The wall 16b is connected to a movable portion (a member 32) of the support 10. The member 16 rotates as the housing 2 rotates. The member 16 is an example of a third member. In the embodiment, as an example, as illustrated in FIG. 2, an upper portion of the post 12 and the member 16 are covered by a cover 19.

In the embodiment, as an example, as illustrated in FIGS. 5 to 7, a sliding mechanism 30 is provided between the wall 16b and the member 14. The sliding mechanism 30 comprises a member 31 and the member 32. The members 31 and 32 both have a circular, plate-like shape (disk-like shape). The members 31 and 32 also both extend along the direction intersecting (direction perpendicular to) the rotation axis Ax. Both of the members 31, 32 may be made of a metallic material (for example, a ferrous material or stainless steel).

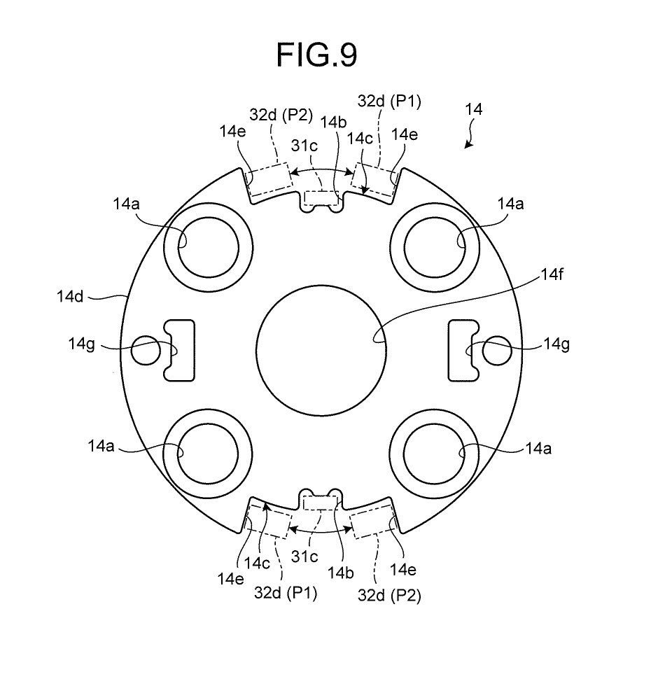

The member 31 is supported by the member 14, that is, by the support 10. Specifically, the member 31 is provided with protrusions 31c (claws, projections) each of which is cut out from an outer edge 31b of the wall 31a at a plurality of (in the embodiment, as an example, two) positions and bent (flexed, formed by bending). The protrusions 31c protrude downward when the support 10 is assembled (toward the member 14, toward a side opposite the member 32, toward a side opposite a direction in which protrusions 32c protrude). As illustrated in FIG. 9, the protrusions 31c are inserted in respective openings 14b provided to the member 14. In this manner, the protrusions 31c (the member 31) are supported by the member 14. The member 31 is an example of a first member. The protrusions 31c are examples of a first protrusion. The openings 14b are examples of a first opening.

The member 32 is supported by the member 16, or that is to say, by the housing 2. Specifically, the member 32 is provided with the protrusions 32c (claws, projections) that are cut out from an outer edge 32b of a wall 32a at a plurality of positions (in the embodiment, as an example, two) and bent (flexed, formed by bending). The protrusions 32c protrudes upward (toward the wall 16b (the member 16), toward a side opposite the member 31, toward a side opposite a direction in which the protrusions 31c protrude). The protrusions 32c are inserted in respective openings 16c provided to the wall 16b. In this manner, the protrusions 32c (the member 32) are engaged onto (supported by) the member 16. The member 32 is an example of a second member. The protrusions 32c are examples of a third protrusion (another protrusion).

The member 32 is also provided with protrusions 32d (claws, projections, sliders) that are cut out from the outer edge 32b of the wall 32a at a plurality of positions (in the embodiment, as an example, two) and bent (flexed, formed by bending). The protrusions 32d are provided at positions different from positions of the protrusions 32c in the rotating direction. In the embodiment, as an example, these two protrusions 32c are provided with respect to each other at an interval of 180 degrees in the rotating direction about the rotation axis Ax. The two protrusions 32d are also provided with respect to each other at an interval of 180 degrees in the rotating direction about the rotation axis Ax. The protrusions 32c are provided at positions different from positions of the protrusion 32d, respectively, by 90 degrees in the rotating direction about the rotation axis Ax. The protrusions 32d protrude downward (toward the member 14, toward a side opposite the direction in which the protrusions 32c protrude) in the configuration in which the support 10 is assembled. The protrusions 32d penetrate through the member 31, and inserted in respective openings 14c provided to the member 14, as illustrated in FIG. 9. In the embodiment, as an example, each of the openings 14c are provided to an outer edge 14d of the member 14 as a cutout having an arc shape. The protrusions 32d are examples of a second protrusion.

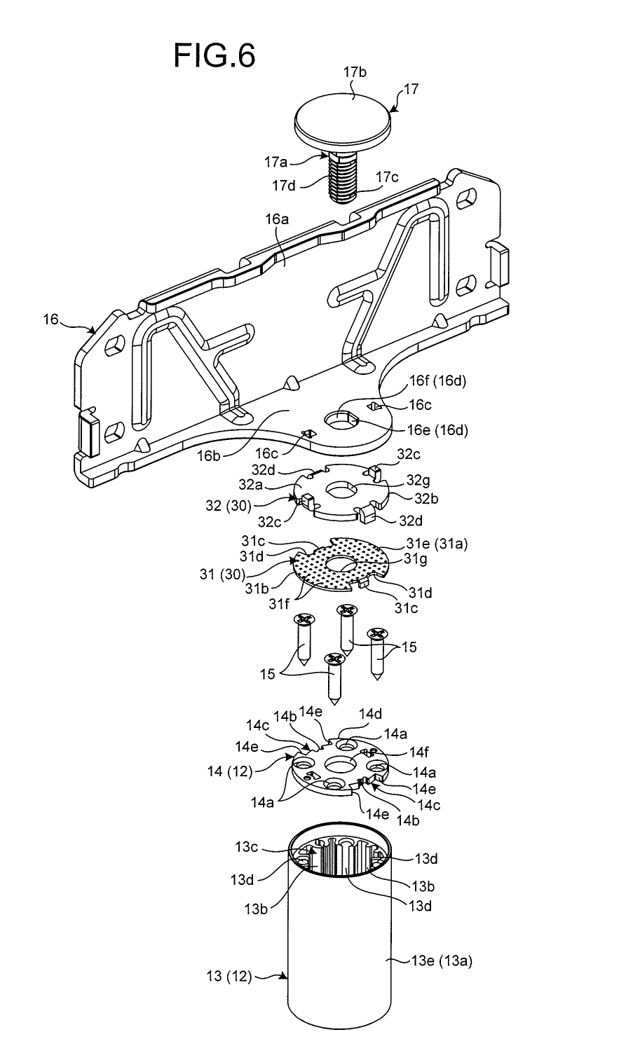

The protrusions 32d are rotated as the housing 2 rotates about the rotation axis Ax, and move in the respective openings 14c. The range within which the protrusion 32d is rotated is defined by two ends 14e (both ends) of the opening 14c along the longitudinal direction (rotating direction about the rotation axis Ax). The protrusions 32d (member 32), and the member 16 and the housing 2 in turn, are allowed to move between a position P1 at which the protrusions 32d abut against respective one ends 14e (see FIG. 9) and a position P2 at which the protrusions 32d abut against the respective other ends 14e (see FIG. 9). In other words, inserted in the respective openings 14c are the protrusions 32d moving between the one position P1 and the other position P2. Alternatively, the range by which the protrusions 32d (the housing 2) are rotated may be determined by engagement of other parts, instead of the protrusions 32d abutting against the respective ends 14e. Furthermore, in the embodiment, as an example, when the member 32 is rotated, a shaft 17a of a bolt 17 (penetrating member) is guided by an opening 14f of the member 14 (see FIG. 5). Alternatively, the rotating member 32 (the housing 2) may be guided by another part. In the embodiment, as an example, as illustrated in FIGS. 6, 7, and 9, each of the openings 14b is connected to corresponding one of the openings 14c, both of which are provided to the member 14, are connected. In other words, each of the openings 14b is configured as a cutout of a portion of the inner circumferential edge (inner side in the radial direction) (in the embodiment, as an example, a center portion in the longitudinal direction (circumferential direction)) of the corresponding opening 14c.

In the embodiment, as an example, the member 31 is provided with openings 31d through which the respective protrusions 32d penetrate. In the embodiment, as an example, each of the openings 31d is provided on the outer edge 31b of the member 31 as an arc-shaped cutout. The protrusions 32d penetrating through the respective openings 31d are rotated and moved in the respective openings 31d as the housing 2 rotates about the rotation axis Ax. In other words, inserted in (penetrated through) the respective openings 31d are the protrusions 32d moving between one position P1 (see FIG. 9) and the other position P2 (see FIG. 9). Therefore, the size of the opening 31d becomes approximately the same as or larger than the size of the opening 14c on the member 14. Each of the protrusions 31c is realized by cutting out a portion of the inner circumferential edge of the corresponding opening 31d (inner side in the radial direction) (in the embodiment, as an example, a center portion in the longitudinal direction (circumferential direction)) and bending (flexing, forming by bending) the cut portion.

In the embodiment, as an example, when the support 10 is assembled, as the housing 2 rotates with respect to the support 10, a planar surface 31e (first surface) of the member 31 and a planar surface 32e (second surface) of the member 32 are rotated relative to each other while being rubbed against each other. In the embodiment, as an example, a plurality of relatively shallow recesses 31f, 32f (dimples) are provided to the surface 31e and to the surface 32e, respectively. The recesses 31f, 32f are provided as dots scattered across the entire surfaces 31e and 32e, respectively. These recesses 31f, 32f may hold (maintain) lubricant (such as grease or oil). Therefore, according to the embodiment, as an example, the member 31 and the member 32 can be rotated more smoothly. Alternatively, the recesses 31f, 32f may be provided one of the member 31 and the member 32. Furthermore, the recesses 31f, 32f may be grooves.

In such configuration, when the size of the area across which the surface 31e is rubbed against the surface 32e (the size of the area in which these surfaces are held in contact) is small, the surface pressure is increased and these surfaces wear out faster. Furthermore, if some edge (a border, a rim, for example, an edge along the radial direction of the rotation axis Ax) is formed in a direction intersecting with rotating direction about the rotation axis Ax in order to achieve openings (e.g., cutouts, penetrating holes) on the surfaces 31e, 32e, that part corresponding to the edge could wear out faster. Furthermore, if the protrusions 31c are to be provided at positions other than the openings 31d, some opening for separating the protrusion 31c and the part other than the protrusion 31c (a wall, a flat portion) would be formed around the area where the protrusion 31c is formed. When the number of openings on the member 31 is increased, the size of the area in which the surface 31e is held in contact with the surface 32e is reduced, and an edge might be formed in the radial direction.

To address this issue, in the embodiment, as an example, in order to achieve the protrusions 31c in a manner corresponding to the configuration of the member 14 in which the opening 14b and the opening 14c are connected, a portion of the inner circumferential edge of each of the openings 31d on the member 31 is cut and bent, as mentioned earlier. In this manner, according to the embodiment, as an example, the protrusions 31c can be provided to the member 31 by taking advantage of the openings 31d. Therefore, according to the embodiment, as an example, it becomes difficult for the size of the area in which the members 31, 32 are held in contact with each other to be reduced, and formation of an edge in a direction intersecting with the rotating direction about the rotation axis Ax can be suppressed, compared to the case in which the openings 14b and the openings 14c provided to the member 14 are interspaced from each other and the protrusions 31c are provided interspaced from the respective openings 31d in a manner corresponding to the openings 14b and the openings 14c. Therefore, according to the embodiment, as an example, abrasion of the members 31, 32 at the parts where the surface 31e, 32e are held in contact with each other can be suppressed.

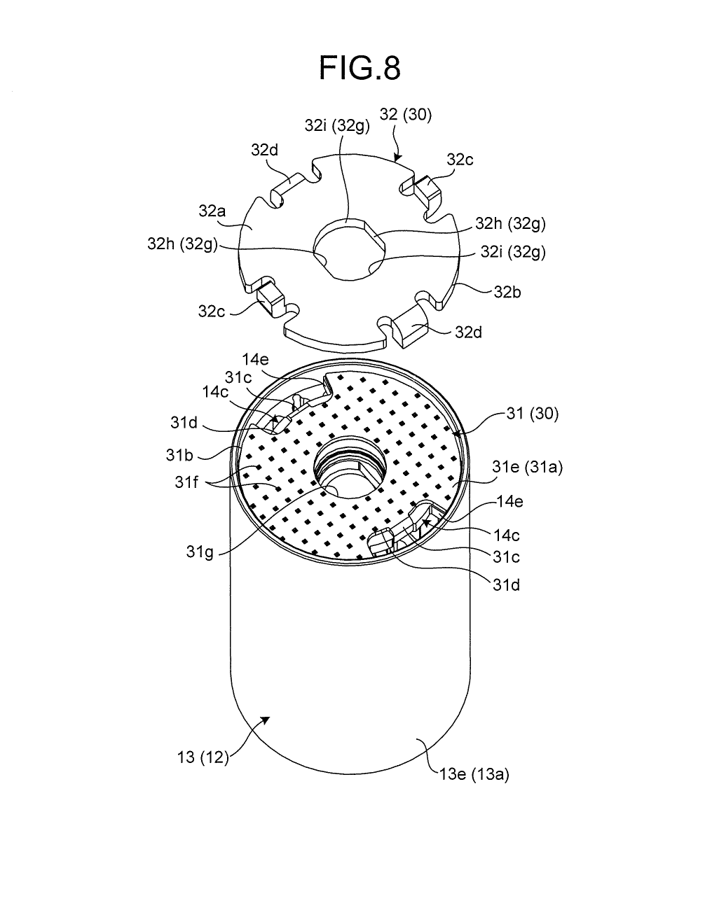

Furthermore, in the embodiment, as an example, as illustrated in FIG. 8, the protrusions 31c provided to the member 31 and the protrusions 32c provided to the member 32 are provided at positions different from each other in the rotating direction about the rotation axis Ax. If the protrusion 31c and the protrusion 32c are provided at positions in which these protrusions overlap each other, when the member 31 and the member 32 rotate as the housing 2 rotates with respect to the support 10, the edges of the openings provided around the protrusion 31c, 32c interfere with each other, and might wear out faster or might cause noise. Furthermore, if an external force or the like is applied during or after the manufacturing process, the root part of the protrusion 31c on the member 31 or the root part of the protrusion 32c on the member 32 might swell (partly protrude) in the direction opposite the direction in which the protrusions 31c, 32c protrude. In such a case, when the member 31 and the member 32 are rotated with respect to each other, the swollen parts might interfere with each other and might result in abrasion, or generate noise. To address this issue, in the embodiment, as an example, the protrusions 31c provided to the member 31 and the protrusions 32c provided to the member 32 are provided at positions different from each other (interspaced with each other) in the rotating direction about the rotation axis Ax. Therefore, according to the embodiment, occurrence of these phenomena is reduced.

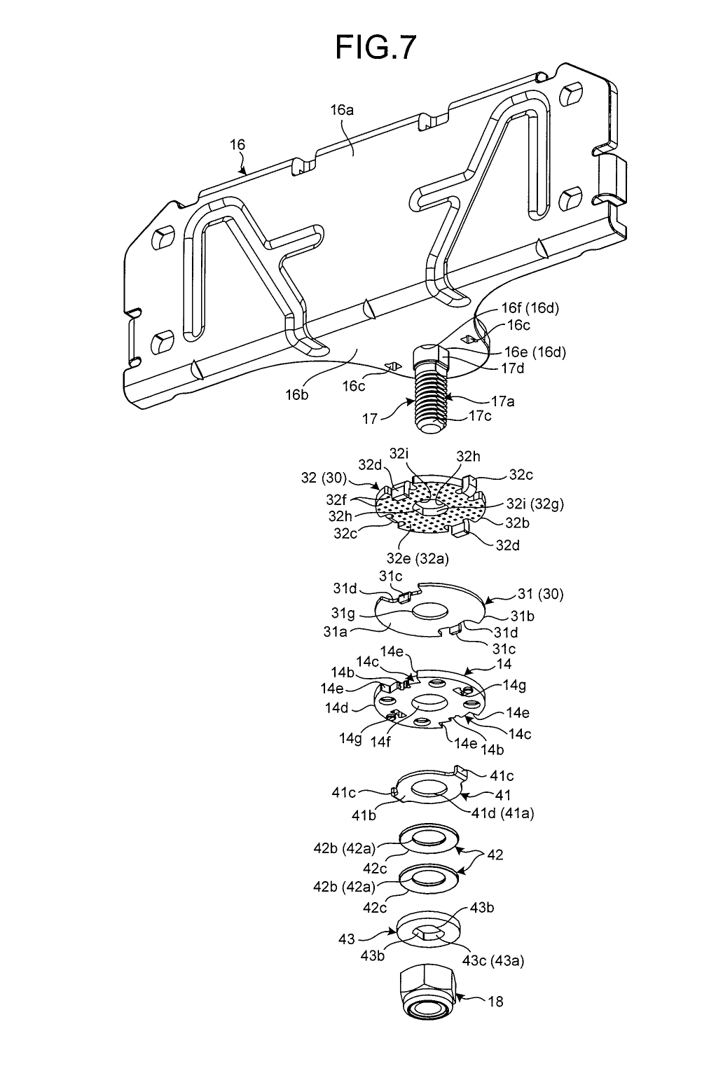

Furthermore, in the embodiment, as an example, as illustrated in FIGS. 6 and 7, the member 16, the member 32, the member 31, and the post 12 (the support 10) are integrated using the bolt 17 and a nut 18 (fixing members). The wall 16b of the member 16, the wall 32a of the member 32, the wall 31a of the member 31, and the member 14 are provided with an opening 16d, an opening 32g, an opening 31g, and the opening 14f, respectively. The shaft 17a of the bolt 17 penetrates through the openings 16d, 32g, 31g, and 14f. The nut 18 is tightened with respect to the bolt 17 from a side of an end 17c of the shaft 17a of the bolt 17 that is on the opposite side of a head 17b. In the embodiment, as an example, as illustrated in FIG. 7, members 41, 42, and 43 in the shape of a ring are provided between the member 31 and the nut 18. These members 41, 42, and 43 are also provided with openings 41a, 42a, and 43a, respectively, through which the shaft 17a of the bolt 17 penetrates.

The shaft 17a of the bolt 17 comprises flat surfaces 17d (chamfered portions). The surfaces 17d are used to prevent each of the components through which the shaft 17a penetrates from rotating. Each of the surfaces 17d extends from the root to the tip of the shaft 17a, including the male screw portion. The surfaces 17d are examples of an positioning portion. In the embodiment, as an example, ends 16e, 32h, and 43b linear in the plan view (viewing in the direction along the rotation axis Ax) are provided to the opening 16d of the member 16, the opening 32g of the member 32, and the opening 43a of the member 43, respectively, in a manner corresponding to the surfaces 17d. The surfaces 17d and the ends 16e, 32h, 43b are provided in a direction intersecting the radial direction of the rotation axis Ax, and positioned nearer to the shaft 17a and the rotation axis Ax than curved portions (ends) 16f, 32i, 43c of the opening 16d, 32g, 43a following the rotating direction about the rotation axis Ax. Therefore, the surfaces 17d and the ends 16e, 32h, 43b can suppress rotations of the member 16, 32, and 43 with respect to the bolt 17 in the rotating direction about the rotation axis Ax (the member 16, 32, and 43 are positioned with respect to the bolt 17 in the circumferential direction). The member 43 is an example of a positioning member.

The members 42 are spring washers (disc washers) with a conical shape. In the embodiment, as illustrated in FIG. 5, each of the members 42 is angled with respect to the rotation axis Ax in a manner so that an inner circumferential edges 42b of the members 42 provided at an inner side in the radial direction are positioned higher than an outer circumferential edges 42c of the members 42 provided at an outer side in the radial direction (closer to the member 41, on the opposite side of the member 43). In other word, each of the members 42 is angled with respect to the rotation axis Ax so as to convex upward. When the bolt 17 and the nut 18 are tightened with respect to each other, the members 42 are elastically deformed from the conically angled form to a flat form, and the reactive force of the elastic deformation acts in the axial direction of the rotation axis Ax, and increases the surface pressure between the surface 31e of the member 31 and the surface 32e of the member 32. The members 42 contribute to provide a sliding resistance, that is, a rotation resistance in the sliding mechanism 30. The member 43 is a locking washer. The member 41 is a thrust plate (a plate, a receiving member) receiving the surface pressure from the members 42. The member 41 is made of a material having a higher abrasion resistance than those of the members 31, 42, for example. The member 41 has a wall 41b (a pressure receiving portion, a receiving portion) and protrusions 41c (claw portions). The wall 41b has a plate-like and ring-like shape. The protrusions 41c protrude upward from the wall 41b (toward the member 31). The protrusions 41c are inserted in respective openings 14g provided to the member 14, and in this manner, the member 41 is engaged with (supported by) the member 14.

According to such configuration, in the part where the members 42 and the member 43 overlap each other, if the inner circumferential edges 42b of the members 42 and the ends 43b of the member 43 are made in contact with each other, the inner circumferential edge 42b and the ends 43b might interfere with each other and the member 42 and the member 43 might wear out faster, or generate noise. To address this issue, in the embodiment, as an example, the inner circumferential edge 42b of the member 42 are provided at a side opposite the member 43, that is, separated from the ends 43b of the member 43. Therefore, according to the embodiment, occurrence of such phenomena is reduced.

Furthermore, in the embodiment, as an example, the member 41 to which the inner circumferential edges 42b of the member 42 is brought into contact does not have any linear ends, and has an inner circumferential edge 41d extending along the rotating direction about the rotation axis Ax. Therefore, according to the embodiment, as an example, because the inner circumferential edge 42b of the member 42 does not interfere with linear ends, fast wearing or generation of noise are suppressed.

Furthermore, in the embodiment, as an example, the member 41 positioned on the protruding side of the member 42 is made of a material with a higher abrasion resistance than that of the member 31, for example. Therefore, according to the embodiment, as an example, fast wearing of the member 31 caused by the member 42 brought into direct contact with the member 31 is suppressed.

As described above, in the embodiment, as an example, the member 14 in the support 10 is provided with the openings 14b (a first opening) in which the respective protrusions 31c (first protrusions) are inserted, and the openings 14c (a second opening) each of which is connected to corresponding one of the openings 14b and in which the respective protrusions 32d (a second protrusion) are inserted. Therefore, according to the embodiment, as an example, the size of the area across which the member 31 and the member 32 are brought into contact can be increased compared with when the opening 14b and the opening 14c are provided separately, and an increase of the surface pressure can be suppressed between the member 31 and the member 32. Furthermore, as an example, compared with when the opening 14b and the opening 14c are provided separately, formation of an edge on the member 31 or the member 32 corresponding to the protrusion 31c or the protrusion 32d is suppressed. Therefore, as an example, wearing of the member 31 or the member 32 caused by such an edge can be suppressed.

Furthermore, in the embodiment, as an example, the member 32 is provided with the protrusions 32c (third protrusions) at positions different from the protrusions 31c (first protrusions), respectively, in the rotating direction. Therefore, as an example, compared with when the protrusions 31c and the protrusions 32c are provided in an overlapping manner, suppressed is wearing of the member 31 and the member 32 or generation of noise caused by edges or swells provided on the member 31 or the member 32 correspondingly to the protrusions 31c or the protrusions 32c.

Furthermore, in the embodiment, as an example, the surface 31e (a first surface) of the member 31 and the surface 32e (a second surface) of the member 32 are provided with the recesses 31f and the recesses 32f, respectively, that can hold lubricant. Therefore, according to the embodiment, as an example, the member 31 and the member 32 can be rotated more smoothly.

Furthermore, in the embodiment, as an example, the support 10 comprises the member 14 (fourth member) having the openings 14b (first openings) and the openings 14c (second openings), and the member 13 (fifth member) connected to the member 14. Therefore, according to the embodiment, as an example, local stiffness or strength of the support 10 can be improved, and labors and costs required in manufacturing the support 10 can be reduced.

Furthermore, in the embodiment, as an example, the member 13 (a fifth member) has a tubular shape, the member 14 (a fourth member) covers one end of the internal space 13c of the member 13. Therefore, according to the embodiment, as an example, labors and costs required in manufacturing the member 13 can be reduced, while ensuring the stiffness and the strength of the member 14 required in supporting the members 31, 32, and the like.

An embodiment of the present invention is explained above. However, the embodiment described above is merely an example, and various modifications of the embodiment are still possible without limitation to the embodiment described above. The technical characteristics described in the embodiment or modifications thereof may be combined as appropriate. Furthermore, specifications of each element (e.g., structure, type, direction, shape, size, length, width, thickness, height, number, arrangement, position, material) may be modified in implementations as appropriate. For example, a washer that is not a conical washer may be used as the washer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a housing comprising a display device;
a support configured to rotatably support the housing;
a first member configured to be supported by the support and comprising a planar first surface; and
a second member configured to be supported by the housing and comprising a planar second surface configured to be rotated while being rubbed against the first surface as the housing rotates, wherein
the support comprises:
a first opening in which a first protrusion provided to the first member is inserted; and
a second opening in which a second protrusion provided to the second member is inserted, the second opening communicating with the first opening, the second protrusion being configured to be rotated between a first position and a second position as the housing rotates.

2. The television receiver of claim 1, wherein the second member comprises a third protrusion configured to protrude toward a side opposite the first member at a position different from the first protrusion in a rotating direction, and configured to be engaged with a third member configured to be rotated with the housing.

3. The television receiver of claim 1, wherein a recess capable of containing lubricant is provided to at least one of the first surface and the second surface.

4. The television receiver of claim 1, wherein the support further comprises:
a fourth member provided with the first opening and the second opening; and
a fifth member configured to be connected to the fourth member.

5. The television receiver of claim 4, wherein
the fifth member has a tubular shape, and
the fourth member is configured to cover one end of an internal space of the fifth member.

6. A television receiver comprising:
a housing comprising a display device;
a support configured to rotatably support the housing;
a first member configured to be supported by the support and comprising a first surface; and
a second member configured to be supported by the housing and comprising a second surface configured to be rotated while being rubbed against the first surface as the housing rotates, wherein
the first member comprises a first protrusion configured to protrude toward a side opposite the second member, and
the second member comprises a second protrusion configured to protrude toward a side opposite the first member at a position different from the first protrusion in a rotating direction.

7. The television receiver of claim 6, wherein the first member and the second member are made of a metallic material.

8. An electronic device comprising:
a housing comprising a display device;
a support configured to rotatably support the housing;
a first member comprising a first surface and made of a metallic material; and
a second member comprising a second surface and made of a metallic material, the second surface being configured to be rotated while being rubbed against the first surface as the housing rotates, wherein
the first member comprises a first protrusion configured to protrude toward a side opposite the second member and configured to be supported by the support, and
the second member comprises a second protrusion configured to protrude toward a side opposite the first member and configured to be supported by the housing.

9. The electronic device of claim 8, wherein at least one of the first surface and the second surface comprises a recess configured to hold lubricant.
